(19) United States
(12) Patent Application Publication
(10) Pub. No.: US 2018/0358532 A1
(43) Pub. Date: Dec. 13, 2018

(54) SYSTEM TO CONVERT IN ELECTRICITY, THE HEAT ASSOCIATED TO THE ENVIRONMENT TEMPERATURE IN THE INTERIOR OF TUNNELS OR SIMILAR

(71) Applicant: Carlos Hernandez, Santiago (CL)

(72) Inventor: Carlos Hernandez, Santiago (CL)

(21) Appl. No.: 15/618,247

(22) Filed: Jun. 9, 2017

(51) Int. Cl. H01L 35/30; E21F 17/00

(52) U.S. Cl. CPC H01L 35/30; E21F 17/00

(57) ABSTRACT

A system for converting into electrical energy the heat associated with the ambient temperature inside tunnels or the like, characterized in that it is formed by a rod type probe (1), which is inserted into the rock that makes up the walls of the Tunnel (5), The heat-trapping surface (3) associated with the ambient temperature which is coupled to at least one heat conversion device (2), which converts it to electrical energy, which in turn is connected to an electronic device, Which captures the energy delivered by the heat converter (2), performs the conversion or adaptation of voltages and current (4), with the aim of transmitting the maximum power to the consumption loads using the generated electric energy.

### BACKGROUND OF THE INVENTION

In all tunnels it has a temperature difference between the air inside the tunnel and the rock walls constituting the tunnel.

Although there are multiple techniques for converting temperature differences into electricity, these are present in domestic and surface applications, not in tunnels, nor have they been used in mining.

The relevance of this invention is to provide a scalable, energy-efficient, heat-conversion system without moving components, which allows optimizing the capture of the heat associated with the ambient temperature available in the air inside the tunnels, cavern, underground Or similar and which, in addition, allows the flow of thermal energy, into the interior of the rock that constitutes the tunnel itself.

Historically, alternative solutions consider using the characteristic that air upon heating rises, and that movement is used for moving parts to generate electricity, which requires frequent maintenance, a task that in the case many tunnels, causes interference in the circulation of Vehicles and people, impacting on the increase of operating costs of the users of these tunnels. In the case of most of the tunnels, the air flows, due to differences in temperature, have very low speeds, so the conversion into electrical energy presents great difficulties associated with available power.

The invention consists of a system that generates electric energy from the heat in tunnels, taking advantage of the temperature difference between the ambient temperature inside the tunnel and the temperature inside the rock that composes the walls of the tunnels.

In particular, in tunnels associated with underground mining it is necessary to electrically energize many sensors, luminaires and signage, both permanently and also provisionally. The above has the difficulty of having to electrically connect these devices and, therefore, install cables and electrical conduit from the electrical distribution center or electrical room, tasks to which a significant amount of human and material resources.

The invention solves this problem of the technique by means of a “System for autonomous Generation of Electricity in tunnels. The system converts into electricity the heat associated with the temperature difference between the environment inside tunnels and the rock. Each system generates more than 0.5 W at more than 1.5 Volt DC”.

As regards the state of the art, we can mention the U.S. Pat. No. 7,124,584, which refers to a system for the generation of energy from a geothermal heat source. The system includes a fluid injection system configured to inject fluid into an underground formation and a fluid withdrawal system configured to extract fluid from the subterranean formation after being heated by the formation. The system further includes a heat transformer configured to receive a first fluid heated by the geothermal heat source at a first temperature and adapted to heat a second fluid at a second temperature through a series of chemical reactions. In addition, the system includes a power generation unit configured to receive the second hot fluid, the second temperature from the heat transformer, to raise the temperature of a third fluid that is used to generate energy.

Another patent for the use of heat to produce electrical energy is patent ES 2298644, which refers to a process for the use of geothermal energy, especially for the generation of electricity, in which a heat carrier medium is introduced into the Ground through at least one feed pipe (1), In which the heat carrier means is driven from at least one outlet opening (2), along a flow distance “S” and through the ground, to at least one outlet opening (3), in the That the evacuation opening (3) is arranged at a greater depth than the outlet opening (2) with a difference of depth “Delta T”, this difference in depth “Delta T” being equal to at least 1/20 of the flow distance “S”, and in which the heated heat carrier medium is again driven back to the earth surface (5) through Less a transport pipe (4) connected to the evacuation opening (3).

### BRIEF DESCRIPTION OF THE FIGURES

In order to better understand the invention, to convert the heat associated with the ambient temperature into tunnels or the like into electrical energy, we will describe it on the basis of the figures which form an integral part of this invention, without this restricting it to obvious modifications that could arise, then we have the following:

FIG. 1 shows the system architecture for producing electrical energy, using tunnel heat or the like.

FIG. 2 shows the detail of a probe (rod) to insert into the rock, the rock interface and the converter.

### Detailed Description of the Several Embodiments

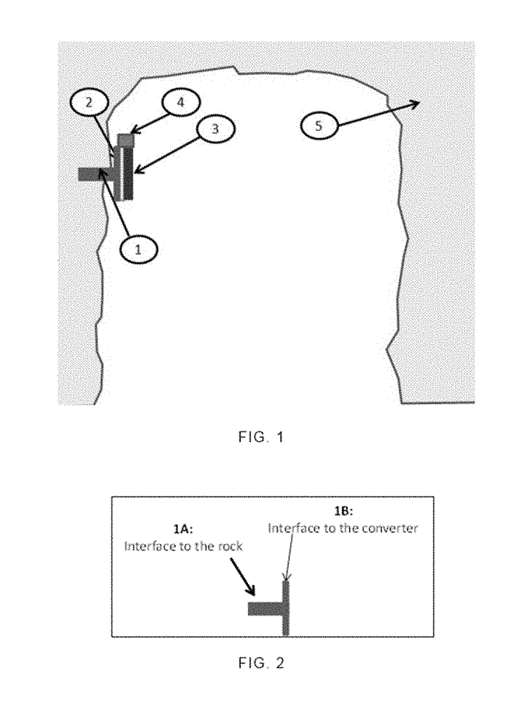

Considering the FIGS. 1 to 2, the system for converting electrical energy, the heat associated with the ambient temperature inside tunnels or the like, is formed by a probe type rod (1), which is inserted into the rock that makes up the walls of the tunnel (5). A heat-trapping surface (3) associated with the ambient temperature which is coupled to at least one heat conversion device (2), which converts the temperature difference between the tunnel environment and the rock to electric energy, the which in turn are connected to an electronic device that allows the adjustment of voltage and current (4) in order to maximize the power transferred to the load-consumption using the power generated.

The rod (1), inserted into the Rock (5), is constituted in turn by two sections (see FIG. 2)

An Insertion Section (1A), with material characteristics and adequate physical design, that allows to optimize the flow of heat towards the interior of the rock.

A section (1B) formed by a platform, which allows the installation of the heat conversion device (2), and its aim is to keep both the platform and the face of the heat-converting device (2) attached to the platform, at a temperature similar to the temperature at which the interior of the rock.

The heat converter 2 comprises a solid state thermopile whose function is to convert the temperature differential into electrical energy.

The device (3) which is exposed to the environment of the tunnel is responsible for the transfer of heat to the upper face of the heat-converting device (2), said face transferring the ambient temperature of the tunnel.

In this way, in the upper face of the thermopile we will have a temperature similar to the ambient temperature of the tunnel, and in the lower face will have a temperature similar to that of the interior of the rock, thus conforming the temperature difference between the faces of the device, which allows, through the transformation of heat, the generation of electric energy.

An electronic circuit collects the electrical energy of the heat converter (2), and modifies the voltage at the output of the converter, converting it into a voltage suitable for use by lighting systems or sensors, transferring electrical power to the devices being energizing. The current supplied will depend on the voltage and power required by the device.

This system allows to have a System that converts Thermal Energy into Electric Energy installed near the devices to be energized inside a tunnel, which is more efficient and economical than the alternative to carry electric power from electrical rooms through cables to the devices to energize.

This system does not require large installations, allowing the energization of equipment of low electrical consumption, at any point inside a tunnel.

What is claimed is:

1. A system to convert into electrical energy, the heat associated with the ambient temperature inside tunnels or the like, CHARACTERIZED in that it is formed by a rod type probe (1), which is inserted into the rock that composes the walls of the tunnel (5), the heat-trapping surface (3) associated with the ambient temperature which is coupled to the (2), which transform it into electrical energy, which in turn is connected to an electronic device, which captures the energy delivered by the heat converter (2), performs the same Conversion or adaptation of voltages and currents (4), with the aim of transmitting the maximum power to the loads-consumptions that use the generated electric energy.

2. A system for converting into electric power, according to claim 1, CHARACTERIZED in that the rod 1 is in turn formed by two sections:
the Insertion Section (1A), with suitable material characteristics and physical design, to optimize the heat flow; and
the converter interface section (1 B), which allows transferring the temperature of the interior of the rock to the converter face, through the stem (1A).

3. A system for converting into electric energy, according to claim 1, CHARACTERIZED in that the heat converter (2) comprises a solid state thermopile, the function of which is to convert the temperature differential into electrical energy.

4. A system for converting into electric power, according to claim 1, CHARACTERIZED by having an electronic circuit, which captures the energy coming from the thermopile and realizes the adaptation of voltage and currents (4), supplying the level of voltage required by the device to be energized.
